(19) United States
(12) Patent Application Publication
(10) Pub. No.: US 2013/0148824 A1
(43) Pub. Date: Jun. 13, 2013

(54) AUTO VOLUME CONTROL METHOD FOR MIXING OF SOUND SOURCES

(71) Applicants: Hyundai Motor Company, Seoul (KR); Kia Motors Corporation, Seoul (KR); C&S Technology Co., Ltd., Seoul (KR)

(72) Inventors: Don Hyoung Lee, Anyang (KR); Dong Ju Lee, Suwon (KR); Tae Hwan Park, Hwaseong (KR); Dae Sung Kim, Hwaseong (KR); Jeong Hwan Hwang, Suwon (KR); Yong Yeon Kim, Gunpo (KR)

(73) Assignees: HYUNDAI MOTOR COMPANY, Seoul (KR); C&S TECHNOLOGY CO., LTD., Seoul (KR); KIA MOTORS CORPORATION, Seoul (KR)

(21) Appl. No.: 13/666,151

(22) Filed: Nov. 1, 2012

(30) Foreign Application Priority Data
Dec. 7, 2011 (KR) 10-2011-0130531

(51) Int. Cl. H03G 3/20

(52) U.S. Cl. 381/107

(57) ABSTRACT

Disclosed is an auto volume control method and system for mixing of sound sources. The control method and system mixes the sound sources by controlling signals of the sound sources automatically inputted by a simple control method, such that the signals from a plurality of sound sources are mixed to prevent an overflow phenomenon of the sound sources from occurring.

### CROSS-REFERENCE TO RELATED APPLICATION

This application claims under 35 U.S.C. §119(a) the benefit of Korean Patent Application No. 10-2011-0130531 filed on Dec. 7, 2011, the entire contents of which are incorporated herein by reference.

### BACKGROUND

(a) Technical Field

The present invention relates to an auto volume control method for mixing of sound sources, particularly for vehicles and the like. More particularly, it relates to a technology that can prevent sound quality from deteriorating due to overflow of the sound sources when a plurality of guiding sound sources are simultaneously inputted and mixed.

(b) Background Art

In a vehicle, a variety of sounds, such as alarm sounds and guiding sounds, are outputted in order to inform a user of various states of and guiding instructions for the vehicle. Therefore, various sounds such as a seat belt warning, a door open warning, an engine check warning, constant-speed driving guiding instructions, parking support guiding instructions, and the like can be outputted.

However, in a situation in which various sounds are outputted simultaneously, the sound sources should be able to be appropriately mix and output these sounds to prevent overflow of the sound sources.

As shown in FIG. 1, in the overflow of sound sources, a bandwidth over an output range A, which a codec or an amplifier can calculate or output, is formed due to intersuperposition of the sound sources when sound sources of two or more channels are inputted and mixed. A signal of a part over the output range disappears, and as a result, the sound is broken in a waveform actually outputted through a speaker after mixing.

Matters described as the background art are just to improve the background of the present invention, but it should not be understood that the matters correspond to the related art which has been already known to those skilled in the art.

### SUMMARY OF THE DISCLOSURE

The present invention has been made in an effort to provide an auto volume control method for mixing of sound sources. In particular, the sound sources are mixed by controlling signals of the sound sources automatically inputted by a simple control method, such that the signals from a plurality of sound sources are mixed.

According to one aspect, the present invention provides an auto volume control method for mixing of sound sources, including: a channel number determining process of determining the number of sound source channels inputted simultaneously; a sound volume reducing process for resetting a presently set volume of each channel volume controlling unit by controlling an inputted volume of each sound source channel to a value divided by the number of the simultaneously inputted sound source channels; a mixing process of mixing the volume-controlled sound source channels; and a volume increasing process of resetting a present set volume of an entire volume controlling unit such that the volume of the mixed signal is controlled by multiplying the present set volume of an entire volume controlling unit by the number of the simultaneously inputted sound source channels.

According to another aspect, the present invention provides an auto volume control device for mixing of sound sources, including: a plurality of digital sound source channels; a plurality of digital volume controlling units provided for each channel to control a volume of a signal outputted from the digital sound source channel; a mixer for mixing output signals of the plurality of digital volume controlling units; a DAC for converting an output of the mixer into an analog signal; an analog volume controlling unit for controlling a volume of the analog signal outputted from the DAC; and a control unit for determining whether the plurality of digital sound source channels are regenerated, dividing a volume presently set in each digital volume controlling unit by the number of the presently regenerated sound source channels and resetting the volume, and multiplying the presently set volume in the analog volume controlling unit by the number of the presently regenerated sound source channels and resetting the volume.

It is understood that the term “vehicle” or “vehicular” or other similar term as used herein is inclusive of motor vehicles in general such as passenger automobiles including sports utility vehicles (SUV), buses, trucks, various commercial vehicles, watercraft including a variety of boats and ships, aircraft, and the like, and includes hybrid vehicles, electric vehicles, plug-in hybrid electric vehicles, hydrogen-powered vehicles and other alternative fuel vehicles (e.g. fuels derived from resources other than petroleum). As referred to herein, a hybrid vehicle is a vehicle that has two or more sources of power, for example both gasoline-powered and electric-powered vehicles.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items.

### BRIEF DESCRIPTION OF THE DRAWINGS

The above and other features of the present invention will now be described in detail with reference to certain exemplary embodiments thereof illustrated the accompanying drawings which are given hereinbelow by way of illustration only, and thus are not limitative of the present invention, and wherein:

FIG. 1 is a diagram showing an overflow phenomenon of sound sources which can occur when a plurality of sound sources are mixed;

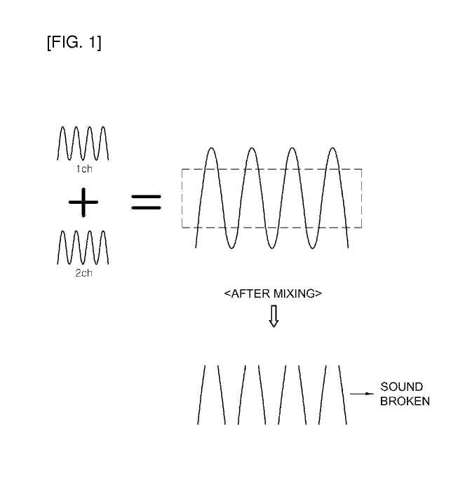

FIG. 2 is a flowchart showing an auto volume control method for mixing of sound sources according to an exemplary embodiment of the present invention; and

FIG. 3 is a diagram showing an auto volume control device for mixing of sound sources according to another exemplary embodiment of the present invention.

It should be understood that the appended drawings are not necessarily to scale, presenting a somewhat simplified representation of various preferred features illustrative of the basic principles of the invention.

In the figures, reference numbers refer to the same or equivalent parts of the present invention throughout the several figures of the drawing.

### DETAILED DESCRIPTION

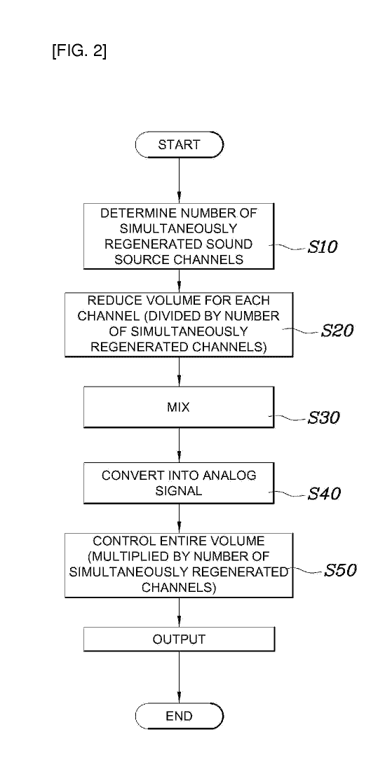

Referring to FIG. 2, an auto volume control method for mixing of sound sources according to an exemplary embodiment of the present invention includes a channel number determining process (S10) of determining the number of sound source channels inputted simultaneously, a sound volume reducing process (S20) in which a presently set volume of each channel volume controlling unit (wherein each channel volume controlling unit controls an inputted volume of each sound source channel) is reset to a value divided by the number of the simultaneously inputted sound source channels, a mixing process (S30) of mixing the volume-controlled sound source channels, a signal converting process (S40) of converting the mixing-completed signal into an analog signal, and a volume increasing process (S50) in which a present set volume of an entire volume controlling unit (wherein the entire volume controlling unit controls the volume of the mixed signal) is reset by multiplying the present set volume of the entire volume controlling unit by the number of the simultaneously inputted sound source channels.

In particular, according to the exemplary embodiment, because the volume of each channel is first decreased to a volume divided by the number of the simultaneously inputted channels and the volumes are mixed and thereafter, followed by increasing the volume increases in proportion to the number of the simultaneously inputted input channels after the sound sources are mixed, when the mixed volume is increased to a volume multiplied by the number of the simultaneously inputted channels, volume overflow is avoided and appropriate sound source mixing is easily accomplished.

According an exemplary embodiment, the sound source channels are digital sound source channels, each channel volume controlling unit is configured by a digital volume controlling unit, and the entire volume controlling unit is configured by an analog volume controlling unit.

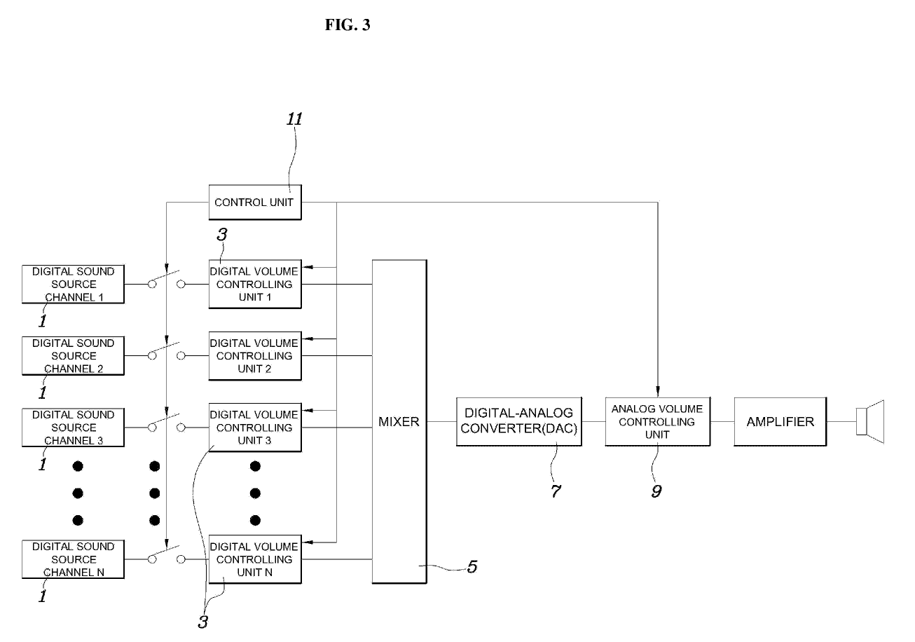

In particular, FIG. 3 depicts one exemplary embodiment of such a device that can implement an auto volume control function for mixing of sound sources. As shown, the device includes a plurality of digital sound source channels 1, a plurality of digital volume controlling units 3 provided for each channel and being configured and arranged to control a volume of a signal outputted from the digital sound source channels 1, a mixer 5 configured and arranged for mixing output signals of the plurality of digital volume controlling units 3, a DAC 7 configured and arranged for converting an output of the mixer into an analog signal, and an analog volume controlling unit 9 configured and arranged for controlling a volume of the analog signal outputted from the DAC 7. A control unit 11 is further configured and arranged for determining whether the plurality of digital sound source channels 1 are regenerated, dividing a volume presently set in each digital volume controlling unit 3 by the number of the presently regenerated sound source channels and resetting the volume (the volume being reset to the presently set volume divided by the number of the presently regenerated sound source channels), and multiplying the presently set volume in the analog volume controlling unit 9 by the number of the presently regenerated sound source channels and resetting the volume (the volume being reset to the presently set volume multiplied by the number of the presently regenerated sound source channels).

In particular, the digital volume controlling unit 3 corresponds to the channel volume controlling unit described in the auto volume control method and the analog volume controlling unit 9 corresponds to the entire volume controlling unit.

In the case where the auto volume control device for mixing of sound sources mixes the sound sources by using the control method, (for example, when the digital volume controlling unit 3 can control the volume from 0 to −31 dB and the analog volume controlling unit 9 can control the volume in the range of 30 to −31 dB), in the case where the number of the simultaneously regenerated sound source channels is 2, then the volumes of two digital volume controlling units 3 are decreased by ½ (−3 dB) and mixed. Thereafter, the volume is compensated (+3 dB) in the analog volume controlling unit 9.

Further when the number of the simultaneously regenerated sound source channels is 4, then the volumes of four inputted channels are decreased by ¼ (−6 dB) in the digital volume controlling unit 3 and synthesized. Thereafter, the volume is compensated (+6 dB) in the analog volume controlling unit 9. As a result, overflow of the sound sources is prevented.

Of course, when the number of the simultaneously regenerated sound source channels is 1, the overflow of the sound sources does not occur, and as a result, the volume is not controlled.

According to the exemplary embodiments of the present invention, control software can be simplified by simplifying the control for mixing the sound sources. As a result, a load of a control micom can be reduced, a misoperation can be reduced that would have otherwise resulted due to a bug, and a development period of a controller can be shortened.

According to the exemplary embodiments of the present invention, the sound sources are mixed by controlling signals of the sound sources automatically inputted by a simple control method in mixing the signals from a plurality of sound sources. As a result, an overflow phenomenon of the sound sources can be prevented.

Further, by simplifying control software, a load of a control micom can be reduced, misoperations due to bug can be reduced, and a development period of a controller can be shortened.

Although the above exemplary embodiment is described as using a plurality of units to perform the above process, it is understood that the above processes may also be performed by a single controller or unit.

Furthermore, the control logic of the present invention may be embodied as non-transitory computer readable media on a computer readable medium containing executable program instructions executed by a processor, controller or the like. Examples of the computer readable mediums include, but are not limited to, ROM, RAM, compact disc (CD)-ROMs, magnetic tapes, floppy disks, flash drives, smart cards and optical data storage devices. The computer readable recording medium can also be distributed in network coupled computer systems so that the computer readable media is stored and executed in a distributed fashion, e.g., by a telematics server or a Controller Area Network (CAN).

While the invention will be described in conjunction with exemplary embodiments, it will be understood that present description is not intended to limit the invention to those exemplary embodiments. On the contrary, the invention is intended to cover not only the exemplary embodiments, but also various alternatives, modifications, equivalents and other embodiments, which may be included within the spirit and scope of the invention as defined by the appended claims.

What is claimed is:

1. An auto volume control method for mixing of sound sources, comprising:
a channel number determining process of determining, by a control unit, the number of sound source channels inputted simultaneously; a sound volume reducing process for resetting, by the control unit, a presently set volume of each channel volume controlling unit that controls an inputted volume of each sound source channel to a value divided by the number of the simultaneously inputted sound source channels;
a mixing process of mixing, by a mixer, the volume-controlled sound source channels; and
a volume increasing process of resetting, by the control unit, a present set volume of an entire volume controlling unit that controls the volume of the mixed signal by multiplying the number of the simultaneously inputted sound source channels.

2. The auto volume control method for mixing of sound sources of claim 1, further comprising a signal converting process of converting, by a digital-analog converter, an output of the mixer into an analog signal after the mixing process and before the volume increasing process.

3. The auto volume control method for mixing of sound sources of claim 1, wherein the sound source channels are digital sound source channels, each channel volume controlling unit is configured by a digital volume controlling unit, and the entire volume controlling unit is configured by an analog volume controlling unit.

4. An auto volume control device for mixing of sound sources, comprising:
a plurality of digital sound source channels;
a plurality of digital volume controlling units provided for each digital sound source channel to control a volume of a signal outputted from each of the digital sound source channels;
a mixer for mixing output signals of the plurality of digital volume controlling units;
a DAC for converting an output of the mixer into an analog signal;
an analog volume controlling unit for controlling a volume of the analog signal outputted from the DAC; and
a control unit for determining whether the plurality of digital sound source channels are regenerated, dividing a volume presently set in each digital volume controlling unit by a number of the presently regenerated sound source channels to thereby reset the volume, and multiplying the presently set volume in the analog volume controlling unit by the number of the presently regenerated sound source channels to thereby reset the volume.

5. A non-transitory computer readable medium containing program instructions executed by a processor or controller, the computer readable medium comprising:
program instructions that provide a command to determine a number of sounds source channels that are simultaneously input;
program instructions that provide a command to reset a presently set volume of each channel volume controlling unit that controls an inputted volume of each sound source channel;
program instructions that provide a command to mix the volume-controlled sound source channels; and
program instructions that provide a command to increase a presently set volume of an entire volume controlling unit that controls the volume of the mixed signal.
